(19) United States
(12) Patent Application Publication
(10) Pub. No.: US 2015/0207034 A1
(43) Pub. Date: Jul. 23, 2015

(54) SEMICONDUCTOR LIGHT EMITTING DEVICE

(71) Applicant: Samsung Electronics Co., Ltd., Suwon-si (KR)

(72) Inventors: Tan SAKONG, Seoul (KR); Byoung Kyun KIM, Seongnam-si (KR); Tong Ik SHIN, Hwaseong-si (KR); Jin Young LIM, Gwacheon-si (KR); Young Sun KIM, Suwon-si (KR); Suk Ho YOON, Seoul (KR)

(73) Assignee: Samsung Electronics Co., Ltd.

(21) Appl. No.: 14/577,826

(22) Filed: Dec. 19, 2014

(30) Foreign Application Priority Data
Jan. 20, 2014 (KR) 10-2014-0006666

(51) Int. Cl. H01L 33/24; H01L 33/32; H01L 33/00; H01L 33/06; H01L 33/02

(52) U.S. Cl. CPC H01L 33/24; H01L 33/06; H01L 33/025; H01L 33/0025; H01L 33/32

(57) ABSTRACT

A semiconductor light emitting device may include a base semiconductor layer formed on a substrate and having defect regions therein; cavities disposed in regions corresponding to the defect regions on the base semiconductor layer; a capping layer disposed to cover at least one region of the base semiconductor layer and the cavities; and a light emitting structure disposed on the capping layer and including a first conductivity-type semiconductor layer, an active layer, and a second conductivity-type semiconductor layer. Lattice defects formed in the light emitting structure may be reduced to enhance luminous efficiency.

### CROSS-REFERENCE TO RELATED APPLICATION

This application claims the benefit of Korean Patent Application No. 10-2014-0006666 filed on Jan. 20, 2014, with the Korean Intellectual Property Office, the disclosure of which is incorporated herein by reference.

### TECHNICAL FIELD

The present disclosure relates to a semiconductor light emitting device.

### BACKGROUND

A light emitting diode (LED) is a device including a material emitting light when electrical energy is applied thereto, in which energy generated through electron-hole recombination in semiconductor junction parts is converted into light to be emitted therefrom. LEDs are commonly employed as light sources in illumination devices, display devices, and the like, and thus, development of LEDs has been accelerated.

In particular, the development and employment of gallium nitride (GaN)-based LEDs has recently increased, and mobile keypads, turn signal lamps, camera flashes, and the like, using such gallium nitride-based LEDs, have been commercialized. Thus, development of general illumination devices using LEDs has accelerated. Like the products to which they are applied, such as the backlight units of large TVs, the headlamps of vehicles, general illumination devices, and the like, applications of light emitting devices are gradually moving toward large-sized products having high outputs and high degrees of efficiency. Accordingly, a method for enhancing light extraction efficiency of a light emitting device used for the purposes is required. In particular, methods for reducing internal defects of semiconductor layers degrading internal light extraction efficiency and enhancing external light extraction efficiency are required.

### SUMMARY

An aspect of the present disclosure may provide a semiconductor light emitting device having enhanced luminous efficiency.

According to an aspect of the present disclosure, a semiconductor light emitting device may include a base semiconductor layer formed on a substrate and having defect regions therein; cavities disposed in regions corresponding to the defect regions on the base semiconductor layer; a capping layer disposed to cover at least one region of the base semiconductor layer and the cavities; and a light emitting structure disposed on the capping layer and including a first conductivity-type semiconductor layer, an active layer, and a second conductivity-type semiconductor layer.

The capping layer may include regions protruded from the defect regions.

The cavities may be surrounded by the base semiconductor layer and the capping layer.

The cavities may be disposed to be spaced apart from one another in the form of a plurality of islands.

The defective regions may be regions in which threading dislocations are formed.

The capping layer may have a substantially uniform thickness on the cavities and on the base semiconductor layer.

The capping layer may have a composition of AlₓIn_{y}Ga_{1-x-y}N (0<x≦1, 0≦y<1).

The cavities may be air gaps filled with air.

The cavities may have a width greater than a thickness thereof.

The cavities may have a quadrangular or trapezoidal cross-section in a direction perpendicular to the substrate.

The base semiconductor layer and the first conductivity-type semiconductor layer may have the same composition.

The base semiconductor layer may be an undoped semiconductor layer.

The light emitting structure may have an uneven lower surface along the capping layer.

The capping layer may have a first thickness on the defective regions and a second thickness greater than the first thickness in regions other than the defective regions.

According to another aspect of the present disclosure, a semiconductor light emitting device may include: a base semiconductor layer formed on a substrate and having a defect region therein; a capping layer covering at least one region of the base semiconductor layer, having a cavity in a region corresponding to the defect region, and having a refractive index value higher than that of the cavity; and a light emitting structure formed on the capping layer and including a first conductivity-type semiconductor layer, an active layer, and a second conductivity-type semiconductor layer each having a refractive index value higher than that of the capping layer.

According to the other aspect of the present disclosure, a semiconductor light emitting device comprising: a base semiconductor layer formed on a substrate and having defect regions therein; cavities in regions corresponding to any defect regions on the base semiconductor layer; a capping layer covering at least one region of the base semiconductor layer and the cavities; and a light emitting structure disposed on the capping layer and including a first conductivity-type semiconductor layer, an active layer, and a second conductivity-type semiconductor layer.

The capping layer has a refractive index value higher than that of the cavities.

The cavities are gaps filled with air.

The cavities are spaced apart from one another in the form of a plurality of islands.

The capping layer includes regions protruding from any defect regions in the base layer.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view schematically illustrating a semiconductor light emitting device according to an exemplary embodiment of the present inventive concepts;

FIG. 2 is an enlarged view of portion ‘A’ of FIG. 1;

FIG. 3 is a perspective view schematically illustrating a configuration of capping layers of FIG. 1;

FIGS. 4 through 8 are cross-sectional views illustrating major processes of a method for manufacturing a semiconductor light emitting device according to an exemplary embodiment of the present inventive concepts;

FIGS. 9 and 10 are views illustrating examples of packages employing a semiconductor light emitting device according to an exemplary embodiment of the present inventive concepts;

FIGS. 11 and 12 are views illustrating examples of backlights employing a semiconductor light emitting device according to an exemplary embodiment of the present inventive concepts;

FIG. 13 is a view illustrating an example of a lighting device employing a semiconductor light emitting device according to an exemplary embodiment of the present inventive concepts; and

FIG. 14 is a view illustrating an example of a headlamp employing a semiconductor light emitting device according to an exemplary embodiment of the present inventive concepts.

### DETAILED DESCRIPTION

Hereinafter, exemplary embodiments of the present disclosure will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

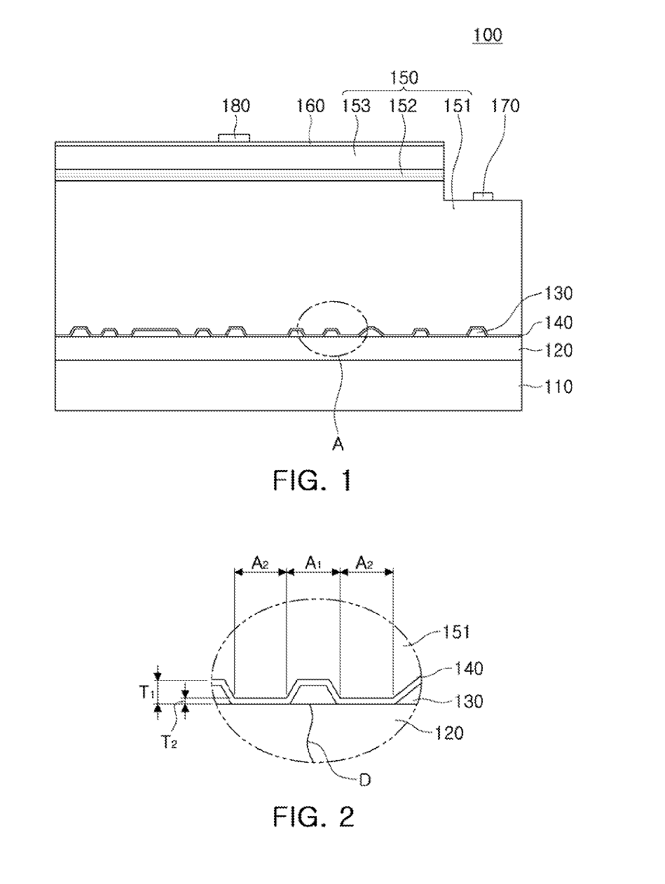

FIG. 1 is a cross-sectional view schematically illustrating a semiconductor light emitting device according to an exemplary embodiment of the present inventive concepts.

Referring to FIG. 1, a semiconductor light emitting device 100 may include a substrate 110, a base semiconductor layer 120 disposed on the substrate 110, cavities 130 formed on the base semiconductor layer 120, a capping layer 140 disposed to cover the cavities 130, and a light emitting structure 150. The light emitting structure 150 may include a first conductivity-type semiconductor layer 151, an active layer 152, and a second conductivity-type semiconductor layer 153. The semiconductor light emitting device 100 may include first and second electrodes 170 and 180 as electrode structures.

In the present disclosure, unless otherwise mentioned, terms such as ‘upper portion’, ‘upper surface’, ‘lower portion’, ‘lower surface’, ‘lateral surface’, and the like, are determined based on the drawings, and in actuality, the terms may be changed according to a direction in which a device is actually disposed.

The substrate 110 may be provided as a semiconductor growth substrate and may be formed of an insulating, a conductive, or a semiconductive material such as sapphire, SiC, MgAl₂O₄, MgO, LiAlO₂, LiGaO₂, GaN, or the like. A sapphire substrate is a crystal having Hexa-Rhombo R3c symmetry, of which lattice constants in c-axial and a-axial directions are approximately 13.001 Å and 4.758 Å, respectively, and has a C-plane (0001), an A-plane (11-20), an R-plane (1-102), and the like. In this case, the C-plane of sapphire crystal allows a nitride thin film to be relatively easily grown thereon and is stable at high temperatures, so the sapphire substrate is commonly used as a nitride growth substrate. When the substrate 110 is formed of silicon (Si), diameter may be increased and price accordingly reduced, facilitating mass-production. Although not shown, a depression and protrusion pattern may be formed on an upper surface of the substrate 110, namely, on a growth surface of the semiconductor layers, and crystallinity, luminous efficiency, and the like, of the semiconductor layers may be enhanced thereby.

The base semiconductor layer 120 is a semiconductor layer grown on the substrate 110. The base semiconductor layer 120 may be formed as an undoped semiconductor layer formed of a nitride such as AlN, GaN, InGaN, or AlGaN. Here, undoped refers to a semiconductor layer which has not undergone an impurity doping process, and the semiconductor layer may have an inherent level of impurity concentration. For example, the base semiconductor layer 120 may relax difference in lattice constants between the substrate 110 formed of, for example, sapphire and the first conductivity-type semiconductor layer 151 formed of GaN to increase crystallinity of the GaN layer. Also, the base semiconductor layer 120 may be formed as a semiconductor layer having a composition identical to that of the first conductivity-type semiconductor layer 151, as described hereinafter.

As illustrated in FIG. 2, the base semiconductor layer 120 may include a defect region including a dislocation defect. The dislocation may be, for example, a threading dislocation D which may be formed due to difference in lattice constants between the substrate 110 and the base semiconductor layer 120. The threading dislocation D may be formed in a direction perpendicular to the substrate 110 and toward a surface of the base semiconductor layer 120 opposing a surface thereof in contact with the substrate 110. The threading dislocation D may dissipate (die away) within the base semiconductor layer 120, or a portion thereof may extend up to the light emitting structure formed on the base semiconductor layer 120 to reduce light extraction efficiency.

The capping layer 140 is formed to cover the base semiconductor layer 120, and have spaces separated from the base semiconductor layer 120 to form the cavities 130 on the defect regions of the base semiconductor layer 120. Also, the capping layer 140 may be formed of a nitride semiconductor, for example, a material having a composition of AlₓIn_{y}Ga_{1-x-y}N(0≦x≦1, 0≦y≦1, 0≦x+y≦1). The capping layer 140 may be configured as a single layer or may be formed as a plurality of layers each having different characteristics such as a doping concentration, a composition, and the like. For example, the capping layer 140 may be formed of a nitride semiconductor such as AlN, AlInN, or AlGaN.

The capping layer 140 may have a thickness sufficient so as not to be damaged by the weight of the light emitting structure 150 formed thereon. Also, the capping layer 140 may be formed to have a thickness sufficient for a sacrificial layer 130a used for forming the cavities 130 to be volatilized during a semiconductor manufacturing process to be described hereinafter.

The capping layer 140 may be formed to cover a region or the entire surface of the base semiconductor layer 120 As shown in FIGS. 2 and 3, the capping layer 140 may include a region A2 in contact with the base semiconductor layer 120 and a region A1 in which a cavity is formed, thus having a protruded region in the region in which the cavity is formed. Also, the capping layer 140 may have a predetermined thickness ranging from 40 Å to 60 Å. However, the present disclosure is not limited thereto and the capping layer 140 may be formed to be relatively thin in the defect region in which the cavity 130 is formed, and relatively thick in other regions.

Each cavity 130 is a space by which one surface of the capping layer 140 and the base semiconductor layer 120 are separated from one another. Each cavity 130 may be formed in various shapes. Each cavity 130 may have a quadrangular or trapezoidal cross-sectional shape and may have a thickness T1 ranging from 0.01 μm to 0.5 μm, and a width A1 ranging from 0.5 μm to 0.6 μm.

The cavity 130 may be formed as a gap filled with air and may have a polyhedral or a dome shape to have a quadrangular or trapezoidal cross-section in a surface perpendicular to the substrate 110.

As mentioned in the manufacturing process described hereinafter, each cavity 130 is formed on the defect region of the base semiconductor layer 120. This is because, the sacrificial layer 130a disposed on the upper surface of the base semiconductor layer 120 is grown to be interspaced apart in an island form in regions region of an upper surface of the base semiconductor layer 120 in which threading dislocations are formed, before the cavities 130 are formed. Thus, since the cavities 130 are formed on the defective region of the base semiconductor layer 120, a defect such as threading dislocation D formed in the base semiconductor layer 120 is prevented from extending to the upper light emitting structure 150. Thus, formation of defects in the light emitting structure 150 can be prevented, alleviating reductions in light extraction efficiency of the semiconductor light emitting device 100. The process of growing the sacrificial layers 130a to be interspaced apart in an island form in the regions of the upper surface of the base semiconductor layer 120 in which threading locations are formed will be described in detail in a manufacturing process described hereinafter.

Also, since the cavities 130 are filled with air, the cavities 130 may also serve as reflectors enhancing light reflectivity due to a difference in refractive indices between the cavities 130 and the light emitting structure 150 formed on the cavities 130. In this case, the refractive index value of the light emitting structure 150 may be greater than that of the capping layer 140 to further enhance light reflectivity.

The light emitting structure 150 may include the first conductivity-type semiconductor layer 151, the active layer 152, and the second conductivity-type semiconductor layer 153. The light emitting structure 150 may be formed on the capping layer 140 and have a lower surface uneven along the capping layer 140.

The first and second conductivity-type semiconductor layers 151 and 153 may respectively be formed of semiconductor doped with an n-type impurity and a p-type impurity, but the present disclosure is not limited thereto and, conversely, the first and second conductivity-type semiconductor layers 151 and 153 may respectively be formed of p-type and n-type semiconductors. The first and second conductivity-type semiconductor layers 151 and 153 may be formed of a nitride semiconductor, e.g., a material having a composition of AlₓIn_{y}Ga_{1-x-y}N (0≦x<1, 0≦y<1, 0≦x+y<1). Each of the semiconductor layers 151 and 153 may be configured as a single layer, or may include a plurality of layers having different characteristics such as different doping concentrations, compositions, and the like. Here, the first and second conductivity-type semiconductor layers 151 and 153 may be formed of an AlInGaP or AlInGaAs semiconductor, in lieu of a nitride semiconductor.

The active layer 152, disposed between the first and second conductivity-type semiconductor layers 151 and 153, emits light having a certain level of energy according to the recombination of electrons and holes and may have a multi-quantum well (MQW) structure in which quantum well layers and quantum barrier layers are alternately laminated. For example, in the case of the nitride semiconductor, a GaN/InGaN structure may be used. A single quantum well (SQW) structure may also be used as needed.

The first and second electrodes 170 and 180 are electrically connected to the first and second conductivity-type semiconductor layers 151 and 153, respectively. The first and second electrodes 170 and 180 may be formed by depositing an electrically conductive material, for example, one or more of silver (Ag), aluminum (Al), nickel (Ni), and chromium (Cr). According to an exemplary embodiment, the first and second electrodes 170 and 180 may be transparent electrodes and may be formed of indium tin oxide (ITO), aluminum zinc oxide (AZO), indium zinc oxide (IZO), ZnO, GZO (ZnO:Ga), In₂O₃, SnO₂, CdO, CdSnO₄, or Ga₂O₃. Also, as illustrated in FIG. 1, a transparent electrode layer 160 may be formed on the second conductivity-type semiconductor layer 153 and the second electrode 180 may be formed on the transparent electrode layer 160 to allow current injected into the second conductivity-type semiconductor layer 153 to be further diffused therein.

The positions and shapes of the first and second electrodes 170 and 180 illustrated in FIG. 1 are an example and may be variously modified according to an exemplary embodiment. Although not shown, an ohmic-electrode layer may be disposed on the second conductivity-type semiconductor layer 153. The ohmic-electrode layer may include, for example, p-GaN including a p-type impurity having a high concentration. Alternatively, the ohmic-electrode layer may be formed of a metal or a transparent conductive oxide.

Since threading dislocations formed in the base semiconductor layer 120 are blocked by cavities 130 in the semiconductor light emitting device 100 configured as described above, threading dislocation reaching the light emitting structure 150 formed on the base semiconductor layer 120 is reduced, enhancing light extraction efficiency. Also, stress due to a difference in lattice constants or coefficients of thermal expansion between the substrate 110 and the base semiconductor layer 120 may be reduced, and external light extraction efficiency may be further enhanced due to the cavities 130 having an air-gap structure filled with air.

Hereinafter, a method for manufacturing the semiconductor light emitting device 100 according to an exemplary embodiment of the present inventive concepts will be described with reference to FIGS. 1 through 8.

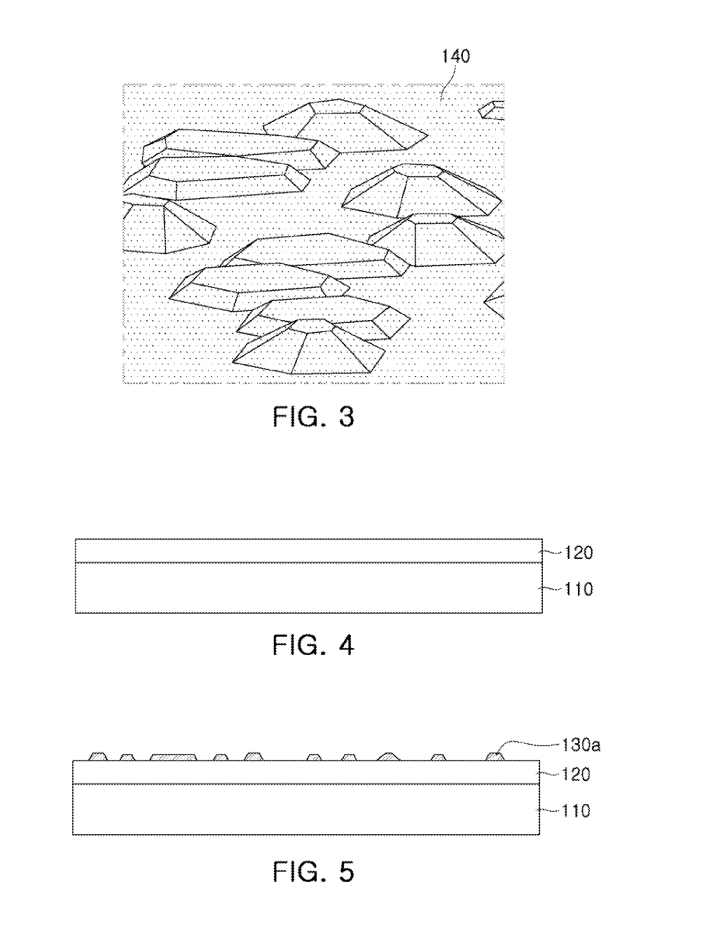

FIG. 1 is a cross-sectional view schematically illustrating a semiconductor light emitting device according to an exemplary embodiment of the present inventive concepts, FIG. 2 is an enlarged view of portion ‘A’ of FIG. 1, FIG. 3 is a perspective view schematically illustrating a configuration of capping layers of FIG. 1, and FIGS. 4 through 8 are cross-sectional views illustrating major processes of a method for manufacturing a semiconductor light emitting device according to an exemplary embodiment. The reference numerals of FIGS. 4 through 8 identical to those of FIGS. 1 through 3 denote the like members, and thus, redundant descriptions will be omitted.

First, as illustrated in FIG. 4, a base semiconductor layer 120 is formed on a substrate 110. As described above, the substrate 110 may be formed of a material such as sapphire, SiC, MgAl₂O₄, MgO, LiAlO₂, LiGaO₂, GaN, or the like, and the base semiconductor layer 120 may be formed of a material such as undoped GaN, AlN, InGaN, AlGaN or the like. In this case, undoped refers to a semiconductor layer which has not undergone an impurity doping process, and the semiconductor layer may have an inherent level of impurity concentration. For example, in a case in which a gallium nitride semiconductor is grown using metal-organic chemical vapor deposition (MOCVD), silicon (Si), or the like, used as a dopant, is included at the level of approximately 10¹⁴ to 10¹⁸/cm³ therein although not intended. The base semiconductor layer 120 may be grown to have a thickness ranging from tens of Å to hundreds of Å at a low temperature ranging from 500° C. to 600° C.

Thereafter, as illustrated in FIG. 5, a sacrificial layer 130a is formed on the base semiconductor layer 120. The sacrificial layer 130a may be formed of a nitride semiconductor including indium (In) and may have a composition of, for example, AlₓIn_{y}Ga_{i-x-y}N (0≦x<1, 0<y≦1).

Specifically, the sacrificial layer 130a may be formed of an indium nitride (InN). When the sacrificial layer 130a is formed of a nitride semiconductor including indium (In), it may have qualities of being relatively easily removed under predetermined conditions such as temperature and atmosphere, and may be spontaneously decomposed under a high temperature condition, for example. However, the material of the sacrificial layer 130a is not limited to a nitride semiconductor including indium (In) and may include, for example, ZnO. Also, the sacrificial layer 130a may be formed of a material obtained by doping Ga, Al, In, Si, C, B, and the like, in the foregoing material.

The sacrificial layer 130a may be formed to be interspaced in an island form, rather than being formed as a continuous layer, on the upper surface of the base semiconductor layer 120 due to a difference in lattice constants from the base semiconductor layer 120. A material used to form the sacrificial layer 130a has a lattice constant significantly different from that of the base semiconductor layer 120. Thus, precursors of a source gas forming the sacrificial layer 130a may be easily adsorbed to have difficulty in making nucleation. Here, however, since the regions of the upper surface of the base semiconductor layer 120 in which the threading dislocations D are unstable in terms of energy due to a strain field, the precursors tend to be adsorbed to the regions in which the threading dislocations D are formed in order to alleviate the unstable energy state.

Thus, nucleation occurs in the regions of the base semiconductor layer 120 in which threading dislocations are formed, automatically forming the islands in the regions. In particular, when the sacrificial layer 130a is formed of a material such as indium nitride (InN), the sacrificial layer 130a has a lattice constant significantly different from that of the base semiconductor layer 120 formed of a material such as GaN, and thus, the sacrificial layer 130a tends to be formed as islands on the base semiconductor layer 120.

In order to form such a sacrificial layer 130a, appropriate process conditions and deposition thickness may be selected. For example, the sacrificial layer 130a may be formed through a heat treatment at a temperature ranging from approximately 500° C. to 700° C. under a reaction gas atmosphere including N₂ and NH₃ and may have a thickness ranging from 0.01 μm to 0.5 μm and a width ranging from 0.5 pm to 0.6 μm. Also, the sacrificial layer 130a has a width greater than a thickness thereof, allowing cavities formed in a follow-up process to have a more stable structure.

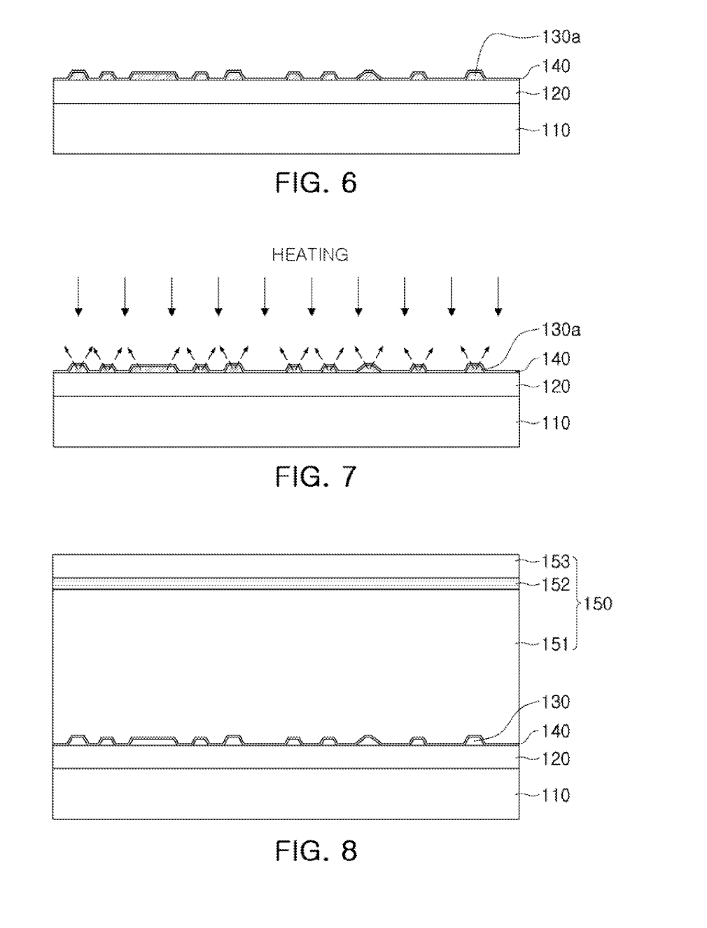

Thereafter, as illustrated in FIG. 6, a capping layer 140 is formed on the base semiconductor layer 120 to cover the sacrificial layer 130a. The capping layer 140 is a structure maintaining cavities 130 formed after the sacrificial layer 130a is volatilized in a follow-up process. The capping layer 140 may have a thickness sufficient for materials of the volatilized sacrificial layer 130a to be discharged appropriately. As illustrated in FIG. 2, the sacrificial layer 130a may have a thickness T2 ranging from 40 Å to 60 Å. If the sacrificial layer 130a is too thick, materials of the volatilized sacrificial layer 130a may not be removed but remain as a metal layer absorbing light within the cavities, potentially degrading light extraction efficiency. In the case of indium nitride (InN), nitrogen (N) has a small enough atomic weight to be easily discharged through the capping layer 140. However, indium (In) has a relatively large atomic weight, and thus, if the capping layer 140 is too thick, indium (In) may not be discharged through the capping layer 140 but remain within the cavities 130.

As described above, the capping layer 140 may be formed of a material having a composition of AlₓIn_{y}Ga_{1-x-y}N (0≦x≦1, 0≦y≦1, 0≦x+y≦1). For example, the capping layer 140 may be formed of a nitride semiconductor such as AlN, AlInN, or AlGaN. The capping layer 140 may be formed in the same manner as that of the sacrificial layer 130a, namely, through a heat treatment at a temperature ranging from approximately 500° C. to 700° C. under a reaction gas atmosphere including N₂ and NH₃, in order to minimize deformation of the sacrificial layer 130a therebelow.

The capping layer 140 may have a substantially uniform thickness and be formed on the sacrificial layer 130a and the base semiconductor layer 120 such that the capping layer 140 has regions protruding from upper portions of the sacrificial layer 130a. Also, the capping layer 140 may be formed to be relatively thin in a region in contact with the sacrificial layer 130a and relatively thick in a region in contact with the base semiconductor layer 120.

Thereafter, as illustrated in FIG. 7, the sacrificial layer 130a is removed.

In the case in which the sacrificial layer 130a is formed of a nitride semiconductor including indium (In), the atmosphere gas of the process of forming the sacrificial layer 130a described above may be changed into the reaction gas atmosphere including N₂ and NH₃ or the temperature for a heat treatment may be increased to be higher by about 50° C. to 500° C. than the growth temperature of the sacrificial layer, and in this state, when the sacrificial layer 130 is heated for approximately five minutes, the sacrificial layer 130a becomes volatile so as to be spontaneously decomposed to be removed. Also, the sacrificial layer 130a may be removed under a hydrogen (H₂) gas atmosphere. The change of the atmosphere gas and the change of the temperature for heat treatment may be individually applied or simultaneously applied. In this manner, since the regions from which the sacrificial layer 130a has been removed are filled with air, the cavities 130 may be formed as air gaps. After the sacrificial layer 130a is removed, re-heating the capping layer 140 may be performed to recover the capping layer 140 that may have been damaged during the volatilization process of the sacrificial layer 130a. For example, the capping layer 140 may be heated at a temperature ranging from approximately 1,020° C. to 1,080° C. to recrystallize the capping layer 140 to recover the capping layer 140 which has been damaged.

Cavities formed as a plurality of layers may be formed by repeating the operations as described above.

Thereafter, as illustrated in FIG. 8, a light emitting structure 150 is formed on the capping layer 140.

A transparent electrode layer 160 (FIG. 1) may thereafter be formed on the light emitting structure 150, the light emitting structure 150 and the transparent electrode layer 160 may be mesa-etched such that a first conductivity-type semiconductor layer 151 is exposed, and, first and second electrodes 170 and 180 respectively may be formed on the first and second conductivity-type semiconductor layers 151 and 153, thus manufacturing the semiconductor light emitting device 100 of FIG. 1. However, the transparent electrode layer 160 may be formed by other than the exemplary embodiment.

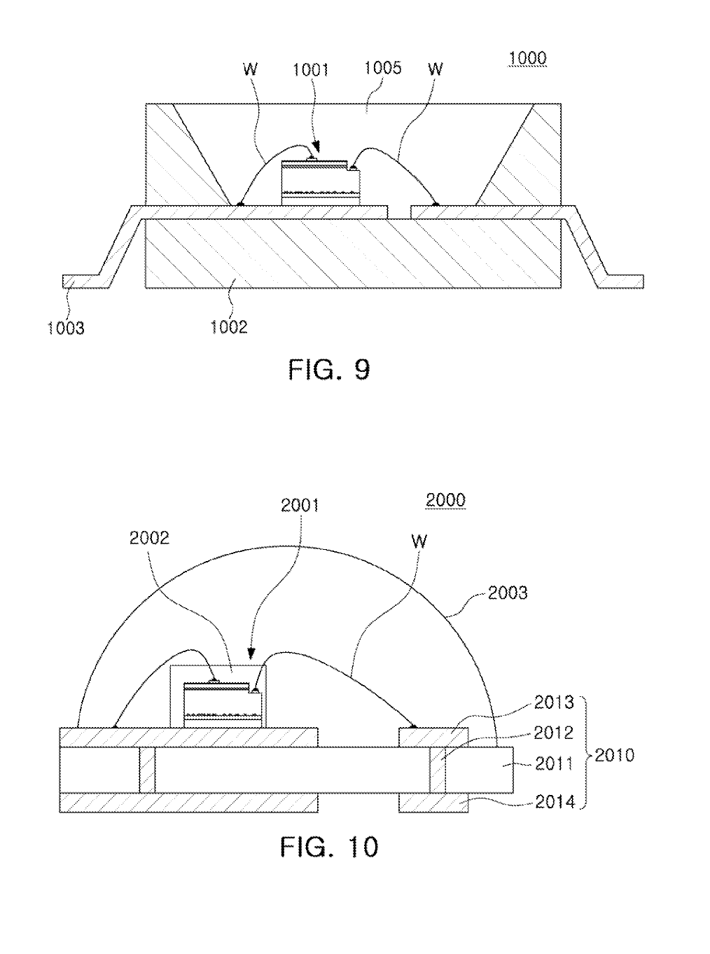

FIGS. 9 and 10 are views illustrating examples of packages employing a semiconductor light emitting device according to an exemplary embodiment of the present inventive concepts.

Referring to FIG. 9, a semiconductor light emitting device package 1000 may include a semiconductor light emitting device 1001, a package body 1002, and a pair of lead frames 1003. The semiconductor light emitting device 1001 may be mounted on the lead frame 1003 and electrically connected to the lead frame 1003 through a wire W. According to an exemplary embodiment, the semiconductor light emitting device 1001 may be mounted on a different region, for example, on the package body 1002, rather than on the lead frame 1003. The package body 1002 may have a cup shape to improve reflectivity efficiency of light. An encapsulant 1005 formed of a light-transmissive material may be disposed in the reflective cup to encapsulate the semiconductor light emitting device 1001, the wire W, and the like. In the present exemplary embodiment, the semiconductor light emitting device package 1000 may include the semiconductor light emitting device 100 illustrated in FIG. 1, and may be manufactured through the method of manufacturing a semiconductor light emitting device illustrated in FIGS. 4 through 8.

Referring to FIG. 10, a semiconductor light emitting device package 2000 may include a semiconductor light emitting device 2001, a mounting board 2010, and an encapsulant 2003. The semiconductor light emitting device 2001 may be mounted on the mounting board 2010 and electrically connected to the mounting board 2010 through a wire W.

The mounting board 2010 may include a board body 2011, an upper electrode 2013, and a lower electrode 2014. Also, the mounting board 2010 may include a through electrode 2012 connecting the upper electrode 2013 and the lower electrode 2014. The mounting board 2010 may be provided as a board such as PCB, MCPCB, MPCB, FPCB, or the like, and the structure of the mounting board 2010 may be altered to have various forms.

The encapsulant 2003 may be formed to have a lens structure with an upper surface having a convex dome shape. However, according to an exemplary embodiment, the encapsulant 2003 may have a lens structure having a convex or concave surface to adjust beam angle of light emitted through an upper surface of the encapsulant 2003. Also, a wavelength conversion unit 2002 may be formed on an upper surface and lateral surfaces of the semiconductor light emitting device 2001.

In the present exemplary embodiment, the semiconductor light emitting device package 2000 may include the semiconductor light emitting device 100 illustrated in FIG. 1 and may be manufactured through the method of manufacturing a semiconductor light emitting device illustrated in FIGS. 4 through 8.

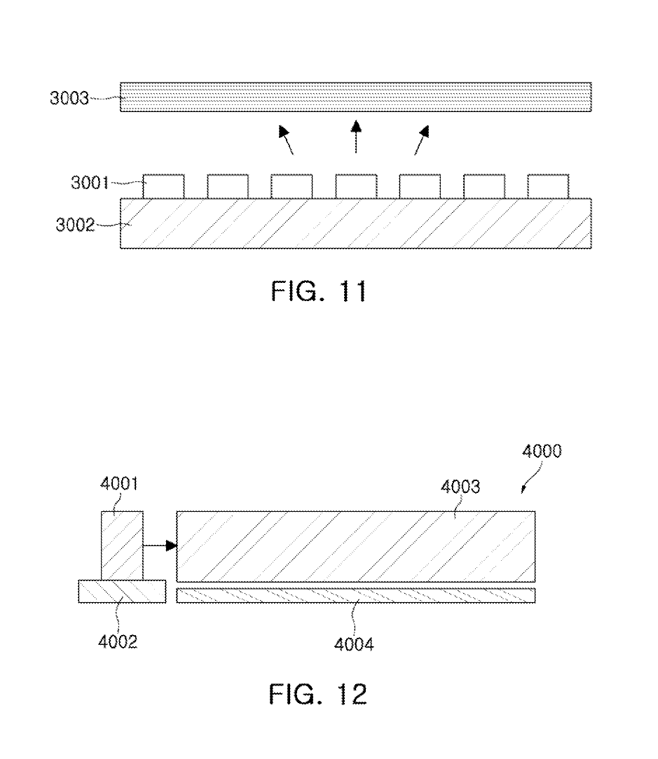

FIGS. 11 and 12 are views illustrating examples of backlights employing a semiconductor light emitting device according to an exemplary embodiment of the present disclosure.

Referring to FIG. 11, a backlight unit 3000 includes light sources 3001 mounted on a substrate 3002 and one or more optical sheets 3003 disposed above the light sources 3001. The semiconductor light emitting device package having the foregoing structure or a structure similar thereto may be used as the light sources 3001. Alternatively, a semiconductor light emitting device may be directly mounted on the substrate 3002 (a so-called COB type) and used.

Unlike the backlight unit 3000 in FIG. 11 in which the light sources 3001 emit light toward an upper side where a liquid crystal display is disposed, a backlight unit 4000 as another example illustrated in FIG. 12 is configured such that a light source 4001 mounted on a substrate 4002 emits light in a lateral direction, and the emitted light may be made to be incident to a light guide plate 4003 so as to be converted into a surface light source. Light passing through the light guide plate 4003 is emitted upwards, and in order to enhance light extraction efficiency, a reflective layer 4004 may be disposed on a lower surface of the light guide plate 4003.

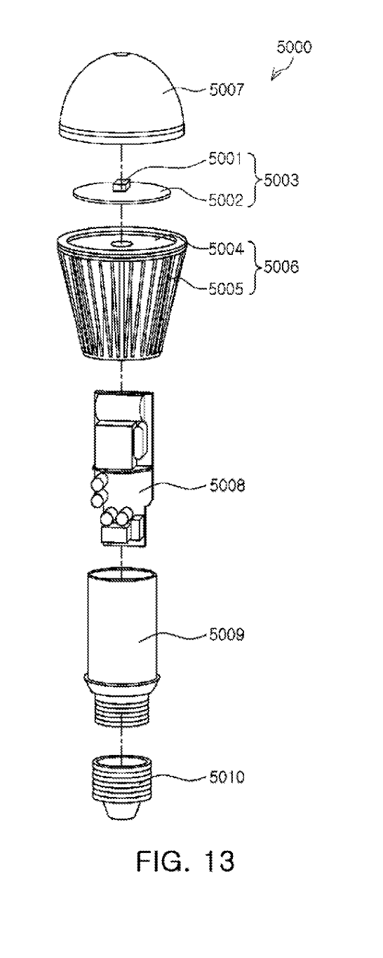

FIG. 13 is a view illustrating an example of a lighting device employing a semiconductor light emitting device according to an exemplary embodiment of the present inventive concepts.

Referring to the exploded perspective view of FIG. 13, a lighting device 5000 is illustrated as, for example, a bulb-type lamp and includes a light emitting module 5003, a driving unit 5008, and an external connection unit 5010. The lighting device 5000 may include external structures such as external and internal housings 5006 and 5009 and a cover unit 5007. The light emitting module 5003 may include a semiconductor light emitting device 5001 having a structure identical or similar to that of the semiconductor light emitting device 100 of FIG. 1 and a circuit board 5002 having the semiconductor light emitting device 5001 mounted thereon. In the present exemplary embodiment, a single semiconductor light emitting device 5001 is shown mounted on the circuit board 5002, but a plurality of semiconductor light emitting devices may be installed as needed. Also, the semiconductor light emitting device 5001 may be manufactured as a package and subsequently mounted, rather than being directly mounted on the circuit board 5002.

The external housing 5006 may serve as a heat dissipation unit and may include a heat dissipation plate 5004 disposed to be in direct contact with the light emitting module 5003 to enhance heat dissipation and heat dissipation fins 5005 surrounding the lateral surfaces of the lighting device 5000. Also, the cover unit 5007 may be installed on the light emitting module 5003 and have a convex lens shape. The driving unit 5008 may be installed in the internal housing 5009 and be connected to the external connection unit 5010 having a socket structure to receive power from an external power source. The driving unit 5008 may serve to convert power into an appropriate current source for driving the semiconductor light emitting device 5001 of the light emitting module 5003, and provide the same. For example, the driving unit 5008 may be configured as an AC-DC converter, a rectifying circuit component, or the like.

Also, although not shown, the lighting device 5000 may further include a communications module.

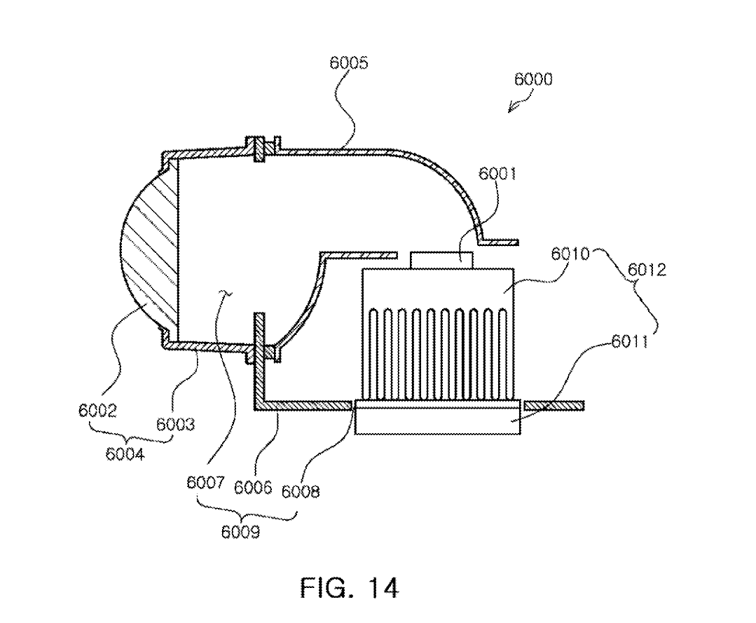

FIG. 14 is a view illustrating an example of a headlamp employing a semiconductor light emitting device according to an exemplary embodiment of the present inventive concepts.

Referring to FIG. 14, a headlamp 6000 used as a vehicle lamp, or the like, may include a light source 6001, a reflective unit 6005, and a lens cover unit 6004. The lens cover unit 6004 may include a hollow guide 6003 and a lens 6002. The light source 6001 may include at least one of the semiconductor light emitting device packages of FIGS. 9 and 10. The headlamp 6000 may further include a heat dissipation unit 6012 outwardly dissipating heat generated by the light source 6001. In order to effectively dissipate heat, the heat dissipation unit 6012 may include a heat sink 6010 and a cooling fan 6011. Also, the headlamp 6000 may further include a housing 6009 fixedly supporting the heat dissipation unit 6012 and the reflective unit 6005, and the housing 6009 may have a body unit 6006 and a central hole 6008 formed in one surface thereof, in which the heat dissipation unit 6012 is coupled. Also, the housing 6009 may have a front hole 6007 formed in the other surface integrally connected to the one surface and bent in a right angle direction. The reflective unit 6005 is fixed to the housing 6009 such that light generated by the light source 6001 is reflected thereby to pass through the front hole 6007 to be emitted outwardly.

As set forth above, according to exemplary embodiments of the present inventive concepts, a semiconductor light emitting device having luminous efficiency enhanced by reducing a lattice defect formed in a light emitting structure may be provided.

Advantages and effects of the present disclosure are not limited to the foregoing content and may be easily understood from the described specific exemplary embodiments of the present inventive concepts.

While exemplary embodiments have been shown and described above, it will be apparent to those skilled in the art that modifications and variations could be made without departing from the spirit and scope of the present disclosure as defined by the appended claims.

What is claimed is:

1. A semiconductor light emitting device comprising:
a base semiconductor layer formed on a substrate and having defect regions therein;
cavities disposed in regions corresponding to the defect regions on the base semiconductor layer;
a capping layer disposed to cover at least one region of the base semiconductor layer and the cavities; and
a light emitting structure disposed on the capping layer and including a first conductivity-type semiconductor layer, an active layer, and a second conductivity-type semiconductor layer.

2. The semiconductor light emitting device of claim 1, wherein the capping layer includes regions protruding from the defect regions.

3. The semiconductor light emitting device of claim 1, wherein the cavities are surrounded by the base semiconductor layer and the capping layer.

4. The semiconductor light emitting device of claim 1, wherein the cavities are spaced apart from one another in the form of a plurality of islands.

5. The semiconductor light emitting device of claim 1, wherein the defect regions are regions in which threading dislocations are formed.

6. The semiconductor light emitting device of claim 1, wherein the capping layer has a substantially uniform thickness on the cavities and on the base semiconductor layer.

7. The semiconductor light emitting device of claim 1, wherein the capping layer has a composition of AlₓIn_{y}Ga_{1-x-y}N (0<x≦1, 0≦y<1).

8. The semiconductor light emitting device of claim 1, wherein the cavities are gaps filled with air.

9. The semiconductor light emitting device of claim 1, wherein the cavities have a width greater than a thickness thereof.

10. The semiconductor light emitting device of claim 1, wherein the cavities have a quadrangular or trapezoidal cross-section in a direction perpendicular to the substrate.

11. The semiconductor light emitting device of claim 1, wherein the base semiconductor layer and the first conductivity-type semiconductor layer have the same composition.

12. The semiconductor light emitting device of claim 1, wherein the base semiconductor layer is an undoped semiconductor layer.

13. The semiconductor light emitting device of claim 1, wherein the light emitting structure has an uneven lower surface along the capping layer.

14. The semiconductor light emitting device of claim 1, wherein the capping layer has a first thickness on the defective regions and a second thickness greater than the first thickness in regions other than the defective regions.

15. A semiconductor light emitting device comprising:
a base semiconductor layer formed on a substrate and having a defect region therein;
a capping layer covering at least one region of the base semiconductor layer, having a cavity in a region corresponding to the defect region, and having a refractive index value higher than that of the cavity; and
a light emitting structure formed on the capping layer and including a first conductivity-type semiconductor layer, an active layer, and a second conductivity-type semiconductor layer each having a refractive index value higher than that of the capping layer.

16. A semiconductor light emitting device comprising:
a base semiconductor layer formed on a substrate and having defect regions therein;
cavities in regions corresponding to any defect regions on the base semiconductor layer;
a capping layer covering at least one region of the base semiconductor layer and the cavities; and
a light emitting structure disposed on the capping layer and including a first conductivity-type semiconductor layer, an active layer, and a second conductivity-type semiconductor layer.

17. The semiconductor light emitting device of claim 16, wherein the capping layer has a refractive index value higher than that of the cavities.

18. The semiconductor light emitting device of claim 16, wherein the cavities are gaps filled with air.

19. The semiconductor light emitting device of claim 16, wherein the cavities are spaced apart from one another in the form of a plurality of islands.

20. The semiconductor light emitting device of claim 16, wherein the capping layer includes regions protruding from any defect regions in the base layer.
